(19) United States
(12) Patent Application Publication
(10) Pub. No.: US 2014/0262129 A1
(43) Pub. Date: Sep. 18, 2014

(54) THERMAL CONTROL OF DEVICE USING FLUID COOLANT

(71) Applicants: Zhihua LI, Chandler, AZ (US); Ronald M. KIRBY, Portland, OR (US); Joe F. WALCZYK, Tigard, OR (US); Kelly P. LOFGREEN, Phoenix, AZ (US)

(72) Inventors: Zhihua LI, Chandler, AZ (US); Ronald M. KIRBY, Portland, OR (US); Joe F. WALCZYK, Tigard, OR (US); Kelly P. LOFGREEN, Phoenix, AZ (US)

(21) Appl. No.: 13/844,192

(22) Filed: Mar. 15, 2013

(51) Int. Cl. H05K 7/20

(52) U.S. Cl. CPC H05K 7/20281
USPC 165/11.1; 165/104.33

(57) ABSTRACT

Assemblies, methods, and systems for controlling the temperature of an electronic device are described. One method includes positioning an electronic device in a chamber and electrically coupling a probe to the electronic device. The method also includes flowing a fluid in contact with the electronic device at a flow rate, the fluid comprising a liquid. A current is applied to the probe to carry out an electronic device testing operation, and a temperature of the electronic device is monitored during the electronic testing operation. The method may also include determining whether a change to the flow rate or temperature is necessary based on the monitored temperature of the electronic device. In one aspect of certain embodiments, the electronic device may be positioned so that each of the sides of the electronic device may be at least partially in contact with the fluid during the electronic device testing operation.

### RELATED ART

When semiconductor devices are tested, test probes are typically used to provide an electrical path between a test system and circuits on a wafer or die, thereby permitting the testing and validation of the circuits thereon, before they are packaged. Up to thousands of test probes may fit within a test head. The device to be tested is moved relative to the test head to bring the pads on the device to be tested into contact with the probes. Heat may be generated in the device and in the test probes during the testing operation.

### BRIEF DESCRIPTION OF THE DRAWINGS

Embodiments are described by way of example, with reference to the accompanying drawings, which are not drawn to scale.

FIG. 1 illustrates a view of features in a testing system including a device under test, in accordance with certain embodiments.

FIG. 2 illustrates a view of features in a testing system including a device under test, in accordance with certain embodiments.

FIG. 3 illustrates a view of features in a testing system, in accordance with certain embodiments.

FIG. 4 illustrates a view of components in a testing system, in accordance with certain embodiments.

FIG. 5 illustrates a flowchart of operations in accordance with certain embodiments;

### DETAILED DESCRIPTION

Reference below will be made to the drawings wherein like structures may be provided with like reference designations. In order to show the structures of various embodiments most clearly, the drawings included herein include diagrammatic representations of various structures. Thus, the actual appearance of the fabricated structures may appear different while still incorporating the claimed structures of the illustrated embodiments. Moreover, the drawings may show only the structures necessary to understand the illustrated embodiments. Additional structures known in the art have not been included to maintain the clarity of the drawings.

When testing is done using test probes in contact with a device (known as device under test or DUT), to ensure product reliability, the DUT should be tested under the expected conditions it may see under actual use conditions. One way to control the temperature of the DUT is to position the non-active side of the DUT on a temperature controlled device. It has been found that such a thermal solution does not provide an optimal temperature control of the DUT. Temperature management of the DUT is beneficial to ensuring the desired test results. Certain embodiments described herein enable more precise temperature control of the DUT, which leads to better testing and improved product reliability.

Certain embodiments relate to assemblies, methods, and systems in which a fluid is delivered to a chamber and brought into appropriate contact with the DUT and at least one of the flow and the temperature of the fluid is controlled so that the temperature of the DUT may be precisely controlled.

FIG. 1 illustrates a cross-sectional view of a test assembly including a device under test (DUT) 10. The DUT 10 may in certain embodiments be a die or a wafer having integrated circuits formed thereon. The DUT 10 may be tested by applying a current through the probes 12 to the contact pads 14 on the DUT 10. The DUT is positioned on a body 16 comprising a thermal head that can be temperature controlled so that an upper surface of the body 16 facing the DUT 10 may be at a desired temperature. Such a thermal head may include heating and cooling elements therein along with pathways to transmit fluid thereon to heat or cool the upper surface. The probes 12 may be positioned in a space transformer 18 that is coupled to an interposer 20. The interposer 20 may act to electrically couple the probes 12 to a printed circuit board (PCB) 22 that includes suitable test circuitry and the like. A stiffener 24 may be positioned on the PCB to ensure that the assembly is suitably rigid.

As illustrated in the embodiment illustrated in FIG. 1, the DUT 10 is positioned in fluid 32. During testing, heat generated can be removed through the fluid 32. The fluid 32 may be selected to have a low thermal resistance. The fluid may be selected from a liquid, a gas, and a vapor (liquid and gas). Embodiments may utilize any fluid with suitable dielectric and heat transfer properties. In certain embodiments, the fluid 32 may comprise a liquid. Examples include, but are not limited to, low dielectric liquids, including, but not limited to, halogenated liquids. Examples of certain halogenated liquids include various Fluorinert™ fluids and Novec™ fluids, available from 3M, including Novec™ engineered fluid HFE-7100 and Fluorinert™ electronic fluids FC-70, FC-40, and FC-3283.

FIG. 1 also illustrates mounting hardware 26, which may act to couple various components together and also act to at least partly define the chamber housing the fluid 32. The fluid 32 may enter the chamber through opening 28 and may exit the chamber through opening 30. Various other components including, but not necessarily limited to, valves, pumps, controllers, filters, and monitors may also be present in the system.

The DUT 10 is positioned on the body 16 in FIG. 1. As noted above, the body 16 may comprise a thermal head having a temperature controlled surface 34 on which the DUT 10 is positioned. The surface 34 has a surface condition that is somewhat roughened so that when the DUT 10 is positioned on the surface 34, the DUT 10 only contacts the surface 34 in certain locations due to the surface roughness of the surface 34. The surface roughness may be controlled so that a gap 36 exists between the DUT 10 and the surface 34. The gap 36 may be controlled so that the fluid 32 can contact various regions of the DUT that are not in direct contact with the surface 34 due to the surface roughness. As a result, the fluid 32 can in certain embodiments flow over a majority of the surface of the DUT 10 facing the body 16 (and other surfaces of the DUT 10) and act as a thermal interface material to remove heat from the DUT 10. In certain embodiments, the surface roughness of the body 10 surface 34 may be formed to permit a surface roughness in the range of about 0.05 μm (microns) to about 0.50 μm. Other gap sizes, larger and smaller, are also possible based at least in part of the contact mechanics between the two surfaces. It should be appreciated that FIGS. 1-2 are not drawn to scale and are instead drawn to make clear the presence of the gap 36 into which the fluid 32 may flow. In addition, in certain embodiments, any gap 36 may be so small, or be non-existent, so that the fluid 32 cannot contact the bottom surface of the DUT 10 that faces surface 34.

FIG. 2 illustrates an assembly in some ways similar to that illustrated in FIG. 1, in accordance with certain embodiments. As seen in FIG. 2, the opening 28 through which fluid 32 may enter the chamber is positioned to extend upward through a bottom surface of the chamber, such as, for example, through the body 16. The opening 30 through which the fluid 32 may exit the chamber is likely positioned to extend through a bottom surface of the chamber, such as, for example, through the body 16.

FIG. 3 illustrates a view of a portion of a test assembly, in accordance with certain embodiments. The assembly includes a mounting block 100 on which the chamber 102 is positioned. A gasket 104 is positioned to ensure that the chamber 102 is properly sealed. A probe array 106 includes the test probes therein and is approximately centered within the chamber 102.

FIG. 4 is a diagram showing various features in a system, in accordance with certain embodiments. The system may include a testing mechanism assembly 200 that comprises various components including a fluid chamber, a thermal head, a device to be tested that is positioned on the thermal head, and a probe card housing test probes. The system also includes a fluid reservoir 202 to house the fluid delivered to and removed from the fluid chamber. A pump 204 is used to deliver the fluid. Temperature and pressure flow controls and monitoring 206 include controls for measuring and regulating the pressure of the fluid as well as the temperature of the fluid. One or more pressure sensors may be provided at various locations along the fluid flow pathway. One or more temperature sensors may be present at various locations in the system including on the DUT. The fluid reservoir 202 or some other portion of the system may include a refrigeration mechanism (and/or heating mechanism) for controlling the temperature of the fluid. The monitoring includes monitoring the temperature of the DUT in one or more locations, so that the temperature and flow rate of the fluid can in turn be controlled to achieve a desired temperature of the DUT during testing.

A valve 208 may be used to regulate delivery and purging of the fluid. In certain embodiments, the fluid delivered to the system comprises a liquid, and after the testing is competed, a gas such as air is run through the system to purge the fluid from the chamber. In addition, an in line filter 210 may be used to filter out impurities from the fluid.

FIG. 5 illustrates a flowchart of operations that may be carried out in accordance with certain embodiments. Box 300 is providing a device in a fluid chamber 70. Box 302 is bring test probes into contact with the device. Box 304 is starting the test procedure. Box 306 is monitoring the temperature of the device during the testing. The temperature of the DUT may be monitored using any suitable mechanism. Box 308 is controlling the temperature of the DUT by controlling the flow rate and temperature of the fluid in the chamber so that a desired temperature is obtained and maintained during the test procedure. Box 310 is completing the test procedure and moving the probes relative to the device so the probes are removed from electrical contact with the device. Various modifications to the above operations may be made, with certain operations being optional. For example, in certain embodiments, the cooling the liquid may not need not be performed.

Experimental testing was carried out to determine whether benefits would occur using the fluid during device testing. The tests compared the temperature conditions including the DUT maximum temperature and the DUT temperature versus time, for a system including fluid flow (FC-3283 liquid) over the DUT during testing versus a system that utilized ambient air and no liquid flow over the DUT during testing. The results indicated that thermal control of the DUT was substantially improved when the liquid was flowed over the DUT. In addition, the maximum temperature reached was substantially lower when the liquid was flowed over the DUT versus the current state of the air, which relies on natural convection of air. Based on experimental and modeling results, at least a 25% improvement in thermal control is expected with the addition of fluid to the active side of the DUT that is in electrical contact with the probes.

A variety of different assembly configurations and component geometries may be used in various embodiments. For example, in certain embodiments, the location of the delivery and exit locations may be varied. In certain embodiments, the presence of the gap 36 enables the fluid to contact all the outer surfaces of the DUT 10. For example, if the DUT 10 is a structure such as a die that is substantially rectangular in shape and has six sides (top side, bottom side and 4 side surfaces), then in certain embodiments at least part of all of the six sides can be in contact with the fluid. In other embodiments, advantages can be obtained even if not all of the sides of the DUT are in contact with the fluid.

The terms “a” and “an” as used herein denote the presence of at least one of the referenced item, and do not denote a limitation of quantity. Terms such as “first”, “second”, and the like may be used herein and do not necessarily denote any particular order, quantity, or importance, but are used to distinguish one element from another. Terms such as “upper”, “lower”, “top”, “bottom”, and the like may be used for descriptive purposes only and indicate the relative positioning of various features. Embodiments may be manufactured, used, and contained in a variety of positions and orientations. The structures of various features in embodiments may be varied from those shown and described herein. In addition, embodiments may be manufactured, used, and contained in a variety of positions and orientations.

In the foregoing Detailed Description, various features are grouped together for the purpose of streamlining the disclosure. This method of disclosure is not to be interpreted as reflecting an intention that the claimed embodiments of the invention require more features than are expressly recited in each claim. Rather, as the following claims reflect, inventive subject matter may lie in less than all features of a single disclosed embodiment.

While certain exemplary embodiments have been described above and shown in the accompanying drawings, it is to be understood that such embodiments are merely illustrative and not restrictive, and that embodiments are not restricted to the specific constructions and arrangements shown and described since modifications may occur to those having ordinary skill in the art.

### EXAMPLES

The following examples pertain to further embodiments.

Example 1 is a method for controlling the temperature of an electronic device, comprising: positioning an electronic device in a chamber; electrically coupling a probe to the electronic device; flowing a fluid in contact with the electronic device at a flow rate; applying a current to the probe to carry out an electronic device testing operation; monitoring a temperature of the electronic device during the electronic testing operation; and determining whether a change to the flow rate is necessary based on the monitored temperature.

In Example 2, the subject matter of Example 1 may optionally include determining whether a change to a temperature of the fluid is necessary based on the monitored temperature of the electronic device.

In Example 3, the subject matter of any of Examples 1-2 may optionally include positioning the electronic device so that the fluid can contact at least a portion of each of the sides of the electronic device.

In Example 4, the subject matter of any of Examples s 1-3 may optionally include positioning the electronic device on a body surface so that a gap remains between at least a portion of the device and the surface.

In Example 5, the subject matter of any of Examples 1-4 may optionally include wherein the gap size is based at least in part on a surface roughness of the body.

In Example 6, the subject matter of any of Examples 1-5 may optionally include wherein the fluid is selected from the group consisting of a liquid, a gas, and a vapor.

In Example 7, the subject matter of any of Examples 1-6 may optionally include wherein the fluid comprises a liquid.

Example 8 is a method for controlling the temperature of an electronic device, comprising: providing a probe in electrical contact with an electronic device, the electronic device including a plurality of sides; and flowing a fluid over the electronic device at a flow rate, so that at least a portion of each of the sides of the electronic device is in contact with the fluid.

In Example 9, the subject matter of Example 8 may optionally include monitoring a temperature of the device and determining whether the flow rate should be modified, based on the temperature of the electronic device.

In Example 10, the subject matter of any of Examples 8-9 may optionally include modifying the flow rate of the fluid based on the temperature of the electronic device.

In Example 11, the subject matter of any of Examples 8-10 may optionally include monitoring a temperature of the electronic device and determining whether a temperature of the fluid should be changed, based on the temperature of the electronic device.

In Example 12, the subject matter of any of any of Examples 8-11 may optionally include positioning the device on a body prior to the flowing the fluid over the electronic device, wherein the device is positioned on the body so that a gap remains between at least a portion of the device and the body.

In Example 13, the subject matter of any of Examples 8-12 may optionally include wherein the gap size is based at least in part on a surface roughness of the body.

In Example 14, the subject matter of any of Examples 8-13 may optionally include wherein the fluid is selected from the group consisting of a liquid, a gas, and a vapor.

In Example 15, the subject matter of any of Examples 8-14 may optionally include wherein the fluid comprises a liquid.

Example 16 is a system for controlling the temperature of an electronic device, comprising: a chamber; an electronic device including contact pads, the electronic device positioned on a surface in the chamber; a testing mechanism including a plurality of probes, the probes adapted to touch the contact pads during electrical testing; an inlet adapted to transmit a fluid into the chamber and onto the electronic device; an outlet adapted to remove fluid from the chamber; and a controller to regulate a flow rate of the fluid into the chamber based on the temperature of the electronic device.

In Example 17, the subject matter of Example 16 may optionally include wherein the surface the electronic device is position on comprises a surface roughness that provides a gap between the surface and a portion of the electronic device.

In Example 18, the subject matter of Example 17 may optionally include wherein the surface roughness between the surface and the electronic device is in the range of 0.05 μm to 0.50 μm.

In Example 19, the subject matter of any of Examples 17-18 may optionally include wherein the gap is sized so that a fluid comprising a liquid can contact a surface of the electronic device within the gap.

In Example 20, the subject matter of any of Examples 16-19 may optionally include wherein the surface the electronic device is position on comprises a surface of a thermal head, the thermal head comprising a structure in which the surface temperature can be controlled.

In Example 21, the subject matter of any of Examples 16-20 may optionally include wherein the controller is also adapted to regulate a temperature of the fluid in the chamber based on the temperature of the electronic device.

Example 22 is a system for controlling the temperature of an electronic device, comprising: chamber means including a surface for housing an electronic device, the electronic device including contact pads; testing mechanism means for testing the electronic device, the testing mechanism means including a plurality of probes, the probes adapted to touch the contact pads during electrical testing; inlet means for transmitting a fluid into the chamber and onto the electronic device, outlet means for removing fluid from the chamber. a chamber; and controller means for regulating a flow rate of the fluid into the chamber based on the temperature of the electronic device.

In Example 23, the subject matter of Example 22 may optionally include wherein the surface the electronic device is position on comprises a surface roughness that provides a gap between the surface and a portion of the electronic device.

In Example 24, the subject matter of Example 23 may optionally include wherein the gap between the surface and the electronic device is in the range of 0.05 μm to 0.50 μm.

In Example 25, the subject matter of any of Examples 23-24 may optionally include wherein the gap is sized so that a fluid comprising a liquid can contact a surface of the electronic device within the gap.

In Example 26, the subject matter of any of Examples 22-25 may optionally include wherein the surface the electronic device is position on comprises a surface of a thermal head, the thermal head comprising structure means for controlling the surface temperature.

In Example 27, the subject matter of any of Examples 22-26 may optionally include wherein the controller means are also adapted to regulate a temperature of the fluid in the chamber based on the temperature of the electronic device.

Example 28 is a computer program product, comprising a computer readable storage medium having computer readable program code embodied therein executable by a processor to perform the method of any one of Examples 16-27.

Example 29 is a computer program product, comprising a computer readable storage medium having computer readable program code embodied therein executable by a processor to implement a method or realize the apparatus of any one of Examples 1-28.

What is claimed:

1. A method for controlling the temperature of an electronic device, comprising:
positioning an electronic device in a chamber;
electrically coupling a probe to the electronic device;
flowing a fluid in contact with the electronic device at a flow rate;
applying a current to the probe to carry out an electronic device testing operation;
monitoring a temperature of the electronic device during the electronic testing operation; and
determining whether a change to the flow rate is necessary based on the monitored temperature.

2. The method of claim 1, further comprising determining whether a change to a temperature of the fluid is necessary based on the monitored temperature of the electronic device.

3. The method of claim 1, further comprising positioning the electronic device so that the fluid can contact at least a portion of each of the sides of the electronic device.

4. The method of claim 1, further comprising positioning the electronic device on a body surface so that a gap remains between at least a portion of the device and the surface.

5. The method of claim 1, wherein the gap size is based at least in part on a surface roughness of the body.

6. The method of claim 1, wherein the fluid is selected from the group consisting of a liquid, a gas, and a vapor.

7. The method of claim 1, wherein the fluid comprises a liquid.

8. A method for controlling the temperature of an electronic device, comprising:
providing a probe in electrical contact with an electronic device, the electronic device including a plurality of sides; and
flowing a fluid over the electronic device at a flow rate, so that at least a portion of each of the sides of the electronic device is in contact with the fluid.

9. The method of claim 8, further comprising, monitoring a temperature of the device and determining whether the flow rate should be modified, based on the temperature of the electronic device.

10. The method of claim 9, further comprising modifying the flow rate of the fluid based on the temperature of the electronic device.

11. The method of claim 8, further monitoring a temperature of the electronic device and determining whether a temperature of the fluid should be changed, based on the temperature of the electronic device.

12. The method of claim 8, further comprising positioning the device on a body prior to the flowing the fluid over the electronic device, wherein the device is positioned on the body so that a gap remains between at least a portion of the device and the body.

13. The method of claim 12, wherein the gap size is based at least in part on a surface roughness of the body.

14. The method of claim 8, wherein the fluid is selected from the group consisting of a liquid, a gas, and a vapor.

15. The method of claim 8, wherein the fluid comprises a liquid.

16. A system for controlling the temperature of an electronic device, comprising:
a chamber;
an electronic device including contact pads, the electronic device positioned on a surface in the chamber;
a testing mechanism including a plurality of probes, the probes adapted to touch the contact pads during electrical testing;
an inlet adapted to transmit a fluid into the chamber and onto the electronic device;
an outlet adapted to remove fluid from the chamber;
a controller to regulate a flow rate of the fluid into the chamber based on the temperature of the electronic device.

17. The system of claim 16, wherein the surface the electronic device is position on comprises a surface roughness that provides a gap between the surface and a portion of the electronic device.

18. The system of claim 17, wherein the gap between the surface and the electronic device is in the range of 0.05 μm to 0.50 μm.

19. The system of claim 17, wherein the gap is sized so that a fluid comprising a liquid can contact a surface of the electronic device within the gap.

20. The assembly of claim 16, wherein the surface the electronic device is position on comprises a surface of a thermal head, the thermal head comprising a structure in which the surface temperature can be controlled.

21. The assembly of claim 16, wherein the controller is also adapted to regulate a temperature of the fluid in the chamber based on the temperature of the electronic device.
